(19) United States
(12) Patent Application Publication
(10) Pub. No.: US 2019/0279547 A1
(43) Pub. Date: Sep. 12, 2019

(54) DISPLAY PANELS AND DISPLAY DEVICES

(71) Applicant: Kunshan Go-Visionox Opto-Electronics Co., Ltd., Kunshan (CN)

(72) Inventor: Yong ZHU, Kunshan (CN)

(21) Appl. No.: 16/424,501

(22) Filed: May 29, 2019

Related U.S. Application Data
(63) Continuation of application No. PCT/CN2018/112460, filed on Oct. 29, 2018.

(30) Foreign Application Priority Data
May 3, 2018 (CN) 201820652769.5

(51) Int. Cl. G09G 3/20; H05K 1/18; G09F 9/30

(52) U.S. Cl. CPC G09G 3/20; H05K 1/189; G09G 2300/0408; H05K 2201/10128; G09G 2300/0426; G09F 9/30

(57) ABSTRACT

The present disclosure relates to a display panel including a substrate and a chip on film. The substrate includes a display area and a non-display area. The display area includes a plurality of pixel units arranged in an array. The pixel units include a plurality rows of pixel units extending in a first direction and a plurality columns of pixel units extending in a second direction perpendicular to the first direction. The display area includes a first display area and a second display area. The non-display area includes a bonding area. The bonding area extends to the first display area along the second direction, such that the pixel units on each row of the first display area are less than the pixel units on each row of the second display area. The chip on film is bonded to the bonding area.

### CROSS-REFERENCES TO RELATED APPLICATIONS

This application is a continuation application of International Application PCT/CN2018/112460, filed on Oct. 29, 2018, which claims the priority benefit of Chinese Patent Application No. 201820652769.5, titled “DISPLAY PANEL AND DISPLAY DEVICE” and filed on May 3, 2018. The entireties of both applications are incorporated by reference herein for all purposes.

### FIELD

The present disclosure relates to the field of display.

### BACKGROUND

With the continuous development of display technology, people have higher and higher demand for display screen, and narrow-frame display device is more and more popular. Generally, a display panel includes a display area and a non-display area disposed around the display area. The non-display area is provided with a trace area, a driving chip bonding area, and the like.

### SUMMARY

Accordingly, in view of the problem that the existing design method of the driver chip bonding area may lead to an excessive occupied area of the non-display area, it is necessary to provide a display panel and a display device having the same.

According to an aspect of the present disclosure, a display panel is provided, which includes a substrate including a display area for displaying information and a non-display area for providing a circuit, the display area including a plurality of pixel units arranged in an array and a signal wire connecting the pixel units, the pixel units arranged in the array including a plurality rows of pixel units arranged along a first direction and a plurality columns of pixel units arranged along a second direction perpendicular to the first direction, the display area including a first display area and a second display area, and the pixel units in the first display area being less than a number of the pixel units in the second display area, the non-display area including a bonding area, the bonding area extending to the first display area along the second direction, to make the pixel unit on each row of the first display area being less than a number of the pixel units on each row of the second display area; and a chip on film bonded to the bonding area.

In an embodiment, in the aforementioned display panel, the bonding area has a leading-out wire provided therein in, and the leading-out wire is correspondingly connected to the signal wire.

In an embodiment, in the aforementioned display panel, the leading-out wire is a transparent trace.

In an embodiment, in the aforementioned display panel, the leading-out wire is electrically connected to the chip on film within the bonding area.

In an embodiment, in the aforementioned display panel, the chip on film is electrically connected to the leading-out wire by covering the leading-out wire.

In an embodiment, in the aforementioned display panel, a flexible circuit board is further included, and the flexible circuit board is provided with a peripheral driving component, and the flexible circuit board is electrically connected to the chip on film.

In an embodiment, in the aforementioned display panel, the chip on film is bent to a surface of the display panel away from the display area.

In an embodiment, in the aforementioned display panel, the signal wire includes a data wire or a scanning wire.

In an embodiment, when the signal wire is a data wire, the bonding area is located at an upper frame or at a lower frame of the display panel; and when the signal wire is a scanning wire, the bonding area is located at a first side frame or a second side frame of the display panel.

According to another aspect of the present disclosure, a display device is provided, which includes the display panel of the aforementioned aspect.

In an embodiment, in the aforementioned display device, a receiving area is further included for receiving a functional component, the receiving area includes a top surface located at the surface of the display panel away from the display area, a projection of the bonding area in the display device overlaps with the top surface of the receiving area.

In an embodiment, in the aforementioned display device, the functional component includes at least one of a camera, a fingerprint recognition component, an iris recognition component, and an earpiece.

The non-display area of the aforementioned display panel and display device includes a bonding area, which extends into the display area along a column direction arranged by the pixel units. The provision of the trace in the display area is changed from a conventional distributed arrangement in the frame of the display panel to a concentrated provision in the bonding area extending into the first display area and connected to the chip on film from the bonding area. Thus, the space of the non-display area occupied by the bonding area can be reduced, an area available for the display area can be increased, and the frame width can be reduced. The display device provided by the present disclosure includes a receiving area for receiving a functional component, and the top surface of the receiving area overlaps with an orthographic projection of the bonding area on the display device, i.e., a space formed by the bonding area projecting forward the display device can accommodate the functional component. In the present disclosure, the bonding area above the receiving area of the functional component is used to bond the chip on film without additionally occupying the space of the non-display region, thereby further increasing the area available for the display area and reducing the frame width.

### BRIEF DESCRIPTION OF THE DRAWINGS

FIG. 1 is a schematic diagram of a display panel in accordance with an embodiment of the present disclosure.

FIG. 2 is a schematic diagram of a display panel in accordance with another embodiment of the present disclosure.

### DETAILED DESCRIPTION OF THE INVENTION

As described above, a display panel usually includes a display area and a non-display area. Conventional design of the driving chip bonding area and the like often lead to an excessive occupied area of the non-display area, thereby making it difficult to narrow the frame of display.

To make the above objects, features and advantages of the present disclosure more apparent, specific embodiments of the present application will be described in detail with reference to the accompanying drawings. Numerous specific details are set forth in the description below to provide a thorough understanding of the application. However, the present application can be implemented in many other ways than those described herein, and those skilled in the art can make similar modifications without departing from the scope of the present application, and thus the present application is not limited by the specific embodiments disclosed below.

It will be understood that when a component is referred to as being “disposed” or “provided” on another component, it can be directly on the other component or intervening components may be present. When a component is referred to as being “connected” or “coupled” to another component, it can be directly connected or coupled to another component or intervening components may be present. The terms “vertical”, “horizontal”, “left”, “right”, and the like, as used herein, are for illustrative purposes only and are not intended to be limited as the only embodiment.

Unless otherwise defined, all terms (including technical and scientific terms) used herein have the same meaning as commonly understood by one of ordinary skill in the art to which this disclosure belongs. The terms used in the specification of the present application are only for the purpose of describing specific embodiments, and not to limit the present application.

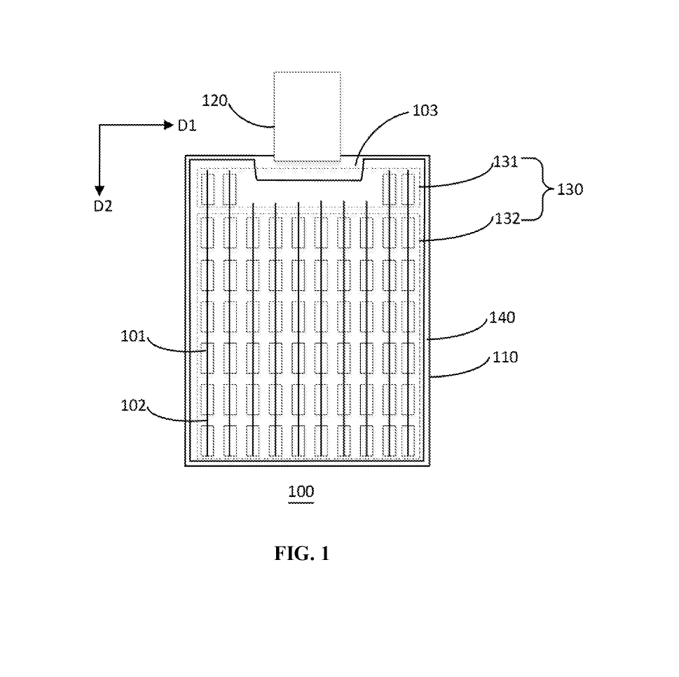

Referring to FIG. 1, a display panel 100 is provided according to an embodiment of the present disclosure, which includes a substrate 110 and a chip on film 120. The substrate 110 includes a display area 130 and a non-display area 140. The display area 130 includes a plurality of pixel units 101 arranged in an array and a signal wire 102 connecting the pixel units 101. The pixel units 101 arranged in the array includes a plurality rows of pixel units 101 arranged in a first direction D1 and a plurality columns of pixel units 101 arranged in a second direction D2 perpendicular to the first direction D1. The display area 130 includes a first display area 131 and a second display area 132. The pixel units 101 in the first display area 131 are less than the pixel units 101 in the second display area 132. It can be understood that the row, the column, the first direction, and the second direction are relative concepts, in other embodiments, the concepts of the row and the column can also be interchanged according to the direction of the display panel.

The non-display area 140 includes a bonding area 103. The bonding area 103 extends to the first display area 131 along the second direction D2, such that the pixel units 101 on each row in the first display area 131 are less than a number of the pixel units on each row in the second display area 132. At the same time, the chip on film 120 is bonded to the bonding area 103.

Specifically, the display area 130 is used to display information, and the non-display area 140 is used to provide a driving circuit. The bonding area 103 is disposed in the non-display area 140, and the bonding area 103 is an area reserved on the substrate 110. The display area 130 and the non-display area 140 are different areas distributed on the substrate 110 according to different functions. The bonding area 103 is an area in the non-display area 130 used to bond the circuit or component. When manufacturing a pixel circuit, the pixel circuit and an organic light-emitting diode, (OLED) is not formed on the bonding area, therefore the bonding area is not used to perform a display in an application. The chip on film 120 is a flexible film provided with a driving chip. The chip on film 120 can be bonded to the bonding area 103.

The non-display area 140 of the display panel 100 includes the bonding area 103 extending into the first display area 131 along the column direction of the pixel arrangement. The display panel 100 generally includes a non-display area (e.g. frames) disposed around the display area, and the bonding area is one of the frames. Since the frame is required to bond the chip on film 120, therefore a width of the frame is resulted to be too wide. In this embodiment, by extending the bonding area 103 into the first display area 131, a length of the bonding area 103 in the first direction is smaller than a length of the frame, and the width thereof in the second direction is larger than a width of other frames in the non-display area 140 except for the bonding area. In this way, the provision of the bonding area 103 can reduce the width of the other frames of the non-display area 140 except for the bonding area, and increase the display area.

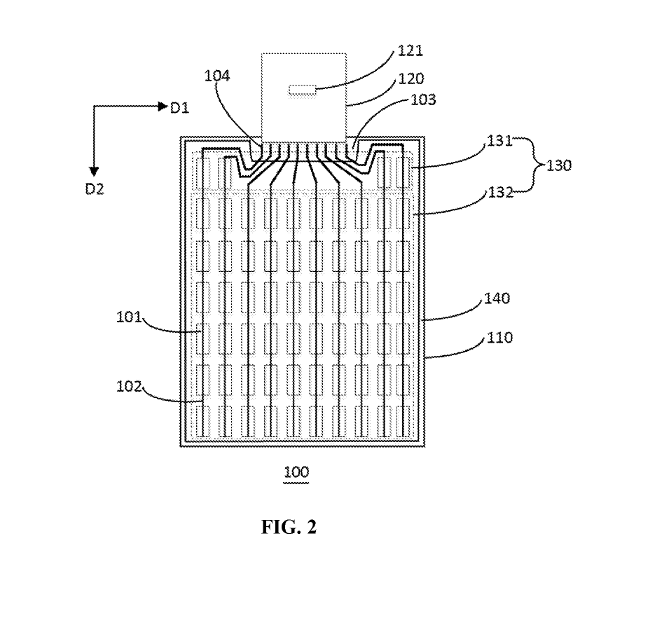

Referring to FIG. 2, in an embodiment, the substrate 110 has a first end and a second end opposite to a front side of the display area 130. The first end and the second end are located in the non-display area 140 with the display area 130 interposed there between. The bonding area 103 can be disposed at one of the first end and the second end of the substrate 110. It can be understood that the first end and the second end are relative concepts, and in other embodiments, the first end and the second end can also be interchanged. In the present embodiment, one end of the substrate 110 having the bonding area 103 is referred to as the first end, and one end of the substrate 110 opposite to the end having the bonding area 103 is referred as the second end. A plurality of leading-out wires 104 are distributed in the bonding area 103, and the plurality of leading-out wires 104 are correspondingly connected to each of the signal wires 102.

Preferably, the leading-out wires 104 can be transparent traces. Since the space formed by the bonding area 103 projecting towards the display device can be used to dispose the functional component, when the functional component is a camera, the leading-out wire 104 is provided as a transparent trace, which can meet a light transmission requirement of the camera and have no effect on imaging of the camera.

The leading-out wires 104 are distributed in the bonding area 103 and are electrically connected to the chip on film 120. The chip on film 120 is connected to the leading-out wires 104 in the bonding area 103, thereby connecting the signal wire 102 and providing a display signal to the pixel units 101 on the signal wire 102. The chip on film 120 can be connected to the leading-out wires 104 via covering the leading-out wires 104. If a covering contact area thereof is large, then wire performance thereof is stable and the reliability is high. Of course, it is not limited to the connection mode of the covering in this embodiment, as long as the chip on film 120 is electrically connected to the leading-out wires 104.

In this embodiment, by multi-using the bonding area 103, the leading-out wires 104 can be disposed, and the chip on film 120 can be bonded to connect the leading-out wires 104 to the chip on film 120. The afore-described arrangement saves position occupations of other frames of the display panel 100, and realizes the narrow-frame display.

In an embodiment, the display panel 100 further includes a flexible circuit board (not shown) electrically connected to the chip on film 120. Peripheral driving components such as resistors and capacitors are disposed on the flexible circuit board. The driver chip on the chip on film 120 cooperates with the peripheral driving components to generate a driving signal and supply the driving signal to the pixel units 101 through the leading-out wires 104. After the chip on film 120 is bonded to the bonding area 103, it can be bent to a surface of the display panel 100 away from the display area 130, i.e., a back surface of the display panel 100.

In an embodiment, the signal wire 102 can be a data wire or a scanning wire. In this embodiment, a shape of the display panel 100 can be a rectangle having unequal length and width. The display panel can include an upper frame and a lower frame extending in the first direction, and a first side frame and a second side frame extending in the second direction. When the signal wire 102 is a data wire, the bonding area 103 can be located at the upper frame or the lower frame of the display panel 100. When the signal wire 102 is a scanning wire, the bonding area 103 can be located at the first side frame or the second side frame of the display panel 100.

In the present embodiment, the bonding area 103 includes a bottom edge and two side edges disposed on both sides of the bottom edge, that is, the bonding area 103 can be rectangular and rounded at right angles of the rectangle. Of course, the size and shape of the bonding area are not limited herein, and can be adjusted according to actual production requirements.

The display panel 100 is generally rectangular with unequal length and width, and can be rounded at the right angles. In a short-side end of the display panel 100, the bonding area 103 is provided, the position of the bonding area can be located at a middle area 103 of the short-side end of the display panel 100, or can be located biased towards one side. The shape of the display panel 100 and the disposed position of the bonding area 103 can be designed according to specific assembled product, and are not limited thereto. The shape of the bonding area 103 is also not limited thereto, and is generally rectangular and rounded at right angles, or can be of other shapes such as a semicircle or the like. The size of the bonding area 103 can be appropriately sized according to the actual production requirements of the product.

A display device is further provided according to another embodiment of the present disclosure, which includes a package shell (not shown). The afore-described display panel 100 is packaged within the package shell.

The display device further includes a receiving area for receiving functional components. The receiving area is formed by the bonding area 103 projecting forward the display device. The functional component can be at least one of a camera, a fingerprint recognition component, an iris recognition component, and an earpiece. When the functional components include a camera, since the substrate 110 and the lead-out wires 104 are both of transparent materials, and the bonding area 103 and the substrate 110 are made of the same material, the bonding area 103 and the lead-out wires 104 have no effect on the light transmission of the camera.

The display panel 100 and the display device provided according to the present embodiment of the present disclosure reserve the bonding area 103 on the substrate, the pixel units and the pixel circuit (not shown) are not provided on the bonding area 103. The bonding area 103 extends into the first display area along the second direction, which can reduce the space occupied by the non-display area and reduce the width of the frames. The leading-out wires 104 of the screen signal wire can be collectively provided in the bonding area 103, and the chip on film 120 is bonded on the bonding area 103, so that the leading-out wires 104 are connected to the chip on film 120 in the bonding area 103. At the same time, the display device further includes a receiving area for receiving the functional component, the receiving area is an area formed by the bonding area 103 projecting toward the display device. The functional component can be located below the bonding area 103. The peripheral functional components of the display panel are collectively disposed in the bonding area 103, and the bonding wires are collectively disposed in the bonding area 103, so that the width of frame of the display panel 100 can be reduced, and the narrow-frame display can be realized.

The technical features of the above embodiments can be arbitrarily combined. For the sake of brevity of description, all possible combinations of the technical features in the above embodiments are not described. However, as long as there is no collision in the combination of these technical features, it should be considered as the scope described in this specification.

The foregoing implementations are merely specific embodiments of the present disclosure, and are not intended to limit the protection scope of the present disclosure. It should be noted that any variation or replacement readily figured out by persons skilled in the art within the technical scope disclosed in the present disclosure shall all fall into the protection scope of the present disclosure. Therefore, the protection scope of the present disclosure shall be subject to the protection scope of the claims.

1. A display panel, comprising:
a substrate comprising a display area for displaying information and a non-display area for providing a circuit, the display area comprising a plurality of pixel units arranged in an array and a signal wire connecting the pixel units, the pixel units arranged in the array comprising a plurality rows of pixel units arranged along a first direction and a plurality columns of pixel units arranged along a second direction perpendicular to the first direction, the display area comprising a first display area and a second display area, and a number of the pixel units in the first display area being smaller than a number of the pixel units in the second display area, the non-display area comprising a bonding area, the bonding area extending to the first display area along the second direction, to make the pixel units on each row in the first display area being less than the pixel units on each row in the second display area; and
a chip on film bonded to the bonding area.

2. The display panel according to claim 1, wherein the bonding area has a leading-out wire provided therein, and the leading-out wire is correspondingly connected to the signal wire.

3. The display panel according to claim 2, wherein the leading-out wire comprises a transparent trace.

4. The display panel according to claim 2, wherein the leading-out wire is electrically coupled to the chip on film within the bonding area.

5. The display panel according to claim 4, wherein the chip on film is electrically coupled to the leading-out wire by covering the leading-out wire.

6. The display panel according to claim 1 further comprising a flexible circuit board on which a peripheral driving component is disposed, the flexible circuit board being electrically connected to the chip on film.

7. The display panel according to claim 1, wherein the chip on film is bent to a surface of the display panel away from the display area.

8. The display panel according to claim 1, wherein the signal wire comprises a data wire or a scanning wire.

9. The display panel according to claim 1, wherein when the signal wire is a data wire, and the bonding area is located at an upper frame or a lower frame of the display panel; and when the signal wire is a scanning wire, the bonding area is located at a first side frame or a second side frame of the display panel.

10. A display device, comprising the display panel of claim 1.

11. The display device according to claim 10, further comprising a receiving area for receiving a functional component, the receiving area comprises a top surface located on a surface of the display panel away from the display area, and a projection of the bonding area in the display device overlaps with the top surface of the receiving area.

12. The display device according to claim 11, wherein the functional component comprises at least one of a camera, a fingerprint recognition component, an iris recognition component, and an earpiece.
